(19) United States
(12) Patent Application Publication
(10) Pub. No.: US 2023/0098450 A1
(43) Pub. Date: Mar. 30, 2023

(54) METHODS AND SYSTEMS FOR A PHOTON DETECTING STRUCTURE AND DEVICE USING COLLOIDAL QUANTUM DOTS

(71) Applicant: OWL AUTONOMOUS IMAGING, INC., Fairport, NY (US)

(72) Inventors: Jacob Eisensmith, Rochester, NY (US); Eugene M. Petilli, Victor, NY (US)

(73) Assignee: OWL AUTONOMOUS IMAGING, INC., FAIRPORT, NY (US)

(21) Appl. No.: 17/955,404

(22) Filed: Sep. 28, 2022

Related U.S. Application Data
(60) Provisional application No. 63/250,131, filed on Sep. 29, 2021.

(51) Int. Cl. H01L 27/146; H04N 5/369; H04N 5/33

(52) U.S. Cl. CPC H01L 27/14681; H01L 27/14683; H04N 5/379; H04N 5/33; H04N 5/378

(57) ABSTRACT

Photosensitive semiconducting devices, such as bipolar junction transistors (BJTs) can be built up over a substrate that may include a read-out integrated circuit (ROIC). Semiconducting layers can be deposited over the substrate and bottom electrodes that are on or at the substrate's top surface. The bottom electrodes may be the input pads of the ROIC. A top electrode is deposited over the semiconducting layers. The semiconducting layers can form BJTs between the bottom electrodes and the top electrode. The top electrode and the bottom electrodes are the BJTs collectors and emitters. The semiconducting layers include a P-type quantum dot layer and a N-type metal oxide layer. The quantum dots act as light sensors for the ROIC because photons absorbed in a semiconducting layer can produce a BJT base current. The BJTs can be formed without requiring a vacuum or patterning of the top electrode.

### CROSS REFERENCE TO RELATED APPLICATIONS

This patent application claims the priority and benefit of U.S. provisional patent application No. 63/250,131, entitled “METHODS AND SYSTEMS FOR A PHOTON DETECTING STRUCTURE AND DEVICE USING COLLOIDAL QUANTUM DOTS,” filed on Sep. 29, 2021, which is herein incorporated by reference in its entirety

### TECHNICAL FIELD

The embodiments relate to colloidal quantum dots (CQDs), CQD light sensors or photon detectors, PIN photodiodes, PINP phototransistors, NINP phototransistors, CQD focal plane arrays, imaging devices, and infrared imaging devices.

### BACKGROUND

Infrared imaging has applications including night vision, surveillance, and autonomous vehicles. Current infrared (IR) imaging equipment using photon detectors based on wafer grown material are expensive. Here, the terms “photon detector” and “light sensor” are used herein to indicate a sensor that detects light such as IR light, visible light, etc. IR light sensors detect IR light such as short wavelength IR (SWIR) light, mid wavelength IR (MWIR) light, and long wavelength IR (LWIR) light. SWIR can include IR light having wavelengths in the range 0.9 μm to 1.7 μm. MWIR can include IR light having wavelengths in the range 3.0 μm to 5.0 μm. LWIR can include IR light having wavelengths in the range 8.0 μm to 14.0 μm. MWIR and LWIR in the thermal imaging band. Photon detectors that are sensitive to MWIR or LWIR light may therefore be used for thermal imaging. Photon detectors based on colloidal quantum dots (CQDs) may be less expensive and thereby provide a route to broader use of infrared imaging. Photon detectors using mercury telluride (HgTe) quantum dots have been prototyped and discussed in the literature. The size of HgTe CQDs has been controlled and it has been shown that differently sized HgTe CQDs are sensitive to different wavelengths of infrared light. Published CQD infrared sensors have had issues with dark current. The dark current issues can be mitigated by actively cooling the sensors to very low temperatures.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure as a prelude to the more detailed description that is presented later.

One aspect of the subject matter described in this disclosure can be implemented as an optoelectronic device. The optoelectronic device can include a bottom electrode, a first quantum to dot layer that is over the bottom electrode, a second quantum dot layer that is on the first quantum dot layer, a third quantum dot layer that is on the second quantum dot layer, and a top electrode that is over the third quantum dot layer, wherein the first quantum dot layer, the second quantum dot layer, and the third quantum dot layer form a PIN junction.

In some implementations of the methods and devices, the devices include a fourth quantum dot layer under the top conductor and on the third quantum dot layer. In some implementations of the methods and devices, the first quantum dot layer, the second quantum dot layer, the third quantum dot layer, and the fourth quantum dot layer are a plurality of HgTe quantum dot layers. In some implementations of the methods and devices, the first quantum dot layer and the fourth quantum dot layer are P-type layers. In some implementations of the methods and devices, the devices include a hole transport layer between the top electrode and the fourth quantum dot layer, wherein the hole transport layer is configured to block electrons and to transport holes. In some implementations of the methods and devices, the devices include an electron transport layer between the bottom electrode and the first quantum dot layer, wherein the electron transport layer is configured to transport electrons and to block holes. In some implementations of the methods and devices, the electron transport layer is a metal oxide layer. In some implementations of the methods and devices, the electron transport layer is a zinc oxide layer or a titanium oxide layer.

In some implementations of the methods and devices, the first quantum dot layer and the fourth quantum dot layer are N-type layers. In some implementations of the methods and devices, the devices include an electron transport layer between the top electrode and the fourth quantum dot layer, wherein the electron transport layer is configured to transport electrons and to block holes. In some implementations of the methods and devices, the devices include a hole transport layer between the bottom electrode and the first quantum dot layer, wherein the hole transport layer is configured to block electrons and to transport holes. In some implementations of the methods and devices, the first quantum dot layer, the second quantum dot layer, and the third quantum dot layer are a plurality of HgTe quantum dot layers. In some implementations of the methods and devices, the bottom electrode is a back side reflector configured to reflect at least 45% infrared light. In some implementations of the methods and devices, the top electrode is configured to pass infrared light into the optoelectronic device. In some implementations of the methods and devices, the top electrode is configured to pass at least 50% of normally incident infrared light into the optoelectronic device. In some implementations of the methods and devices, the second quantum dot layer is a primary photoactive region that absorbs photons and produces charge carriers. In some implementations of the methods and devices, the second quantum dot layer is configured to produce a plurality of charge carriers from a plurality of photons within an infrared wavelength range.

In some implementations of the methods and devices, the second quantum dot layer is configured to produce a plurality of charge carriers from a plurality of photons within a wavelength range, and the bottom electrode is configured to reflect the photons in the wavelength range. In some implementations of the methods and devices, the top electrode is configured to pass the photons in the wavelength range into the optoelectronic device.

In some implementations of the methods and devices, the devices include a transimpedance amplifier that is configured to amplify a signal produced at the bottom electrode. In some implementations of the methods and devices, the devices include an antireflective coating on the top electrode.

In some implementations of the methods and devices, the devices include a substrate that is configured with a bottom electrode array that includes the bottom electrode, and a focal plane array that includes a plurality of optoelectronic devices that includes the optoelectronic device, wherein the focal plane array is on the substrate. In some implementations of the methods and devices, a plurality of transimpedance amplifiers is configured to amplify a plurality of pixel signals produced by the focal plane array, and the pixel signals include a pixel signal produced by the optoelectronic device. In some implementations of the methods and devices, the focal plane array includes a top electrode layer formed using a single conductive layer, and the top electrode layer includes the top electrode.

Another aspect of the subject matter described in this disclosure can be implemented in a method for fabricating an optoelectronic device. The method can include providing a substrate that has a bottom electrode, depositing a first quantum dot layer over the bottom electrode, depositing a second quantum dot layer on the first quantum dot layer, depositing a third quantum dot layer on the second quantum dot layer, and depositing a top electrode over the third quantum dot layer, wherein the first quantum dot layer, the second quantum dot layer, and the third quantum dot layer form a PIN junction.

In some implementations of the methods and devices, the first quantum dot layer is a first P-type mercury telluride quantum dot layer. In some implementations of the methods and devices, the method includes doping the first quantum dot layer to P-type using a solution that includes nanoparticle cations and nanoparticle anions, wherein the nanoparticle anions are chalcogen anions, and the nanoparticle cations are cations of at least one of silver, nickel, antimony, or tin. In some implementations of the methods and devices, the first quantum dot layer is a first P-type mercury telluride quantum dot layer. In some implementations of the methods and devices, the second quantum dot layer is deposited as a series of applications of an intrinsic silver telluride quantum dot solution. In some implementations of the methods and devices, the third quantum dot layer is a first N-type silver telluride quantum dot layer. In some implementations of the methods and devices, the third quantum dot layer is a first N-type mercury telluride quantum dot layer. In some implementations of the methods and devices, the fourth quantum dot layer is a second P-type colloidal quantum dot layer.

In some implementations of the methods and devices, an electron transport layer is deposited between the bottom electrode and the first quantum dot layer. In some implementations of the methods and devices, a hole transport layer is deposited between the top electrode and the fourth quantum dot layer. In some implementations of the methods and devices, the fourth quantum dot layer is a second P-type mercury telluride quantum dot layer. In some implementations of the methods and devices, the fourth quantum dot layer is a second P-type silver telluride quantum dot layer. In some implementations of the methods and devices, the first quantum dot layer is a P-type layer. In some implementations of the methods and devices, the method includes doping the fourth quantum dot layer to P-type using a solution that includes nanoparticle cations and nanoparticle anions, wherein the nanoparticle anions are chalcogen anions, and the nanoparticle cations are cations of at least one of silver, nickel, antimony, or tin.

Yet another aspect of the subject matter described in this disclosure can be implemented in a method for fabricating an optoelectronic device. The method can include providing a substrate that includes a readout integrated circuit (ROIC) and an array of bottom electrodes configured as a plurality of inputs to the ROIC, depositing a first quantum dot layer over the array of bottom electrodes, depositing a second quantum dot layer on the first quantum dot layer, depositing a third quantum dot layer on the second quantum dot layer, and depositing a top electrode layer over the third quantum dot layer, wherein the first quantum dot layer, the second quantum dot layer, and the third quantum dot layer form a PIN junction.

In some implementations of the methods and devices, an electron transport layer is deposited between the array of bottom electrodes and the first quantum dot layer. In some implementations of the methods and devices, a hole transport layer is deposited between the top electrode layer and the fourth quantum dot layer. In some implementations of the methods and devices, the second quantum dot layer is deposited without patterning the first quantum dot layer, the third quantum dot layer is deposited without patterning the second quantum dot layer, the fourth quantum dot layer is deposited without patterning the third quantum dot layer, and the top electrode is deposited without patterning the fourth quantum dot layer. In some implementations of the methods and devices, the first quantum dot layer, the second quantum dot layer, the third quantum dot layer, and the fourth quantum dot layer stay unpatterned. In some implementations of the methods and devices, the top electrode layer stays unpatterned. In some implementations of the methods and devices, the top electrode layer is patterned, is configured as a common electrode, and is configured to allow light to pass into the PIN junction.

Still yet another aspect of the subject matter described in this disclosure can be implemented by a method for fabricating an optoelectronic device. The method can include depositing a CQD layer that contains a quantum dot cation and a quantum dot cation, obtaining a first solution that includes nanoparticle cations and nanoparticle anions, wherein the nanoparticle anions are chalcogen anions, and the nanoparticle cations are cations of at least one of silver, nickel, antimony, or tin. The method can also include obtaining a second solution that includes a quantum dot precursor dissolved in a solvent, using the first solution to produce a nanoparticle layer on the CQD layer, wherein the nanoparticle layer includes the nanoparticle cations and the nanoparticle anions, and contacting the nanoparticle layer with the second solution, wherein the quantum dot precursor undergoes cation exchange with the nanoparticle cations, thereby doping the film of colloidal quantum dots with cations released from the nanoparticles.

In some implementations of the methods and devices, the CQD layer is a HgTe CQD layer, the quantum dot cations are Hg quantum dot cations, and the quantum dot anions are Te quantum dot anions. In some implementations of the methods and devices, the quantum dot anions are Te quantum dot anions and the nanoparticle anions are Te anions. In some implementations of the methods and devices, the quantum dot anions are Te quantum dot anions and the nanoparticle anions are anions of at least one of oxygen, sulfur, or selenium. In some implementations of the methods and devices, the quantum dot precursor is HgCl₂, PbCl₂ or InCl₃. In some implementations of the methods and devices, the solvent includes at least one of water, methanol, propanol.

A further aspect of the subject matter described in this disclosure can be implemented by an optoelectronic device. The optoelectronic device can include a substrate, a bottom electrode at a top surface of the substrate, a plurality of semiconducting layers deposited over the bottom electrode and the substrate, and a top electrode deposited over the plurality of semiconducting layers, wherein the plurality of semiconducting layers form a bipolar junction transistor (BJT) between the bottom electrode and the top electrode, the top electrode and the bottom electrode are a collector electrode and an emitter electrode of the BJT, the BJT includes a collector contacting the collector electrode, the BJT includes an emitter contacting the emitter electrode, and the semiconducting layers include a BJT base formed at least in part using a quantum dot layer.

A yet further aspect of the subject matter described in this disclosure can be implemented by an optoelectronic device. The optoelectronic device can include a substrate that includes a read-out integrated circuit (ROIC) that includes an array of input pads, a plurality of semiconducting layers deposited over the input pads and the substrate, and a top electrode deposited over the plurality of semiconducting layers, wherein the plurality of semiconducting layers forms a plurality of BJTs between the input pads and the top electrode, the BJTs include a plurality of collectors and a plurality of emitters, the top electrode and the input pads are the collector electrodes and the emitter electrodes of the BJTs, the collectors are contacting the collector electrodes, the emitters are contacting the emitter electrodes, the semiconducting layers include a P-type quantum dot layer, the semiconducting layers include a N-type metal oxide layer, and the BJTs form a focal plane array of an image sensor.

A still yet further aspect of the subject matter described in this disclosure can be implemented by method. The method can include obtaining a substrate that has a bottom electrode at a top surface of the substrate, depositing a plurality of semiconducting layers over the bottom electrode and the substrate, and depositing a top electrode over the plurality of semiconducting layers, wherein the plurality of semiconducting layers form a bipolar junction transistor (BJT) between the bottom electrode and the top electrode, the top electrode and the bottom electrode are a collector electrode and an emitter electrode of the BJT, the BJT includes a collector contacting the collector electrode, the BJT includes an emitter contacting the emitter electrode, the plurality of semiconducting layers include a P-type quantum dot layer, and the plurality of semiconducting layers include a N-type metal oxide layer.

In some implementations of the methods and devices, light absorbed by one of the semiconducting layers produces a current that is amplified by the BJT. In some implementations of the methods and devices, a first one of the semiconducting layers is deposited over the bottom electrode and the substrate, a second one of the semiconducting layers is deposited over the first one of the semiconducting layers, a third one of the semiconducting layers is deposited over the second one of the semiconducting layers, the first one of the semiconducting layers is a P-type polysilicon layer, the second one of the semiconducting layers is an N-type metal oxide layer, and the third one of the semiconducting layers is an P-type quantum dot layer. In some implementations of the methods and devices, a first one of the semiconducting layers is deposited over the bottom electrode and the substrate, a second one of the semiconducting layers is deposited over the first one of the semiconducting layers, a third one of the semiconducting layers is deposited over the second one of the semiconducting layers, the first one of the semiconducting layers is an N-type metal oxide layer, the second one of the semiconducting layers is an P-type quantum dot layer, and the third one of the semiconducting layers is a quantum dot layer that is doped N-type or intrinsically N-type.

In some implementations of the methods and devices, the second one of the semiconducting layers and the third one of the semiconducting layers are HgTe quantum dot layers. In some implementations of the methods and devices, the semiconducting layers include a P-type quantum dot layer, and the P-type quantum dot layer that is a HgTe quantum dot layer. In some implementations of the methods and devices, the bottom electrode is a back side reflector configured to reflect at least 45% infrared light. In some implementations of the methods and devices, the top electrode is configured to pass infrared light into the optoelectronic device. In some implementations of the methods and devices, the top electrode is configured to pass at least 50% of normally incident infrared light into the optoelectronic device. In some implementations of the methods and devices, a first one of the semiconducting layers is deposited over the bottom electrode and the substrate, a second one of the semiconducting layers is deposited over the first one of the semiconducting layers, a third one of the semiconducting layers is deposited over the second one of the semiconducting layers, and the second one of the semiconducting layers is a photoactive region that absorbs photons and produces charge carriers. In some implementations of the methods and devices, a first one of the semiconducting layers is deposited over the bottom electrode and the substrate, a second one of the semiconducting layers is deposited over the first one of the semiconducting layers, a third one of the semiconducting layers is deposited over the second one of the semiconducting layers, and the second one of the semiconducting layers is configured to produce a plurality of charge carriers from a plurality of photons within an infrared wavelength range.

In some implementations of the methods and devices, a first one of the semiconducting layers is deposited over the bottom electrode and the substrate, a second one of the semiconducting layers is deposited over the first one of the semiconducting layers, a third one of the semiconducting layers is deposited over the second one of the semiconducting layers, and the second one of the semiconducting layers is configured to produce a plurality of charge carriers from a plurality of photons within a wavelength range, and the bottom electrode is configured to reflect the photons in the wavelength range. In some implementations of the methods and devices, the top electrode is configured to pass the photons in the wavelength range into the optoelectronic device.

In some implementations of the methods and devices, the substrate includes a read-out integrated circuit (ROIC) and an array of bottom electrodes configured as a plurality of input pads of the ROIC, the bottom electrodes include the bottom electrode, the semiconducting layers and the top electrode form a plurality of BJTs, and the BJTs form a focal plane array of an image sensor. In some implementations of the methods and devices, light absorbed by one of the semiconducting layers produces a current that is amplified by the BJTs. In some implementations of the methods and devices, the semiconducting layers stay unpatterned. In some implementations of the methods and devices, the semiconducting layers and the top electrode stay unpatterned. In some implementations of the methods and devices, the semiconducting layers and the top electrode are unpatterned layers.

These and other aspects will become more fully understood upon a review of the detailed description, which follows. Other aspects, features, and embodiments will become apparent to those of ordinary skill in the art, upon reviewing the following description of specific, exemplary embodiments in conjunction with the accompanying figures. While features may be discussed relative to certain embodiments and figures below, all embodiments can include one or more of the advantageous features discussed herein. In other words, while one or more embodiments may be discussed as having certain advantageous features, one or more of such features may also be used in accordance with the various embodiments discussed herein. In similar fashion, while exemplary embodiments may be discussed below as device, system, or method embodiments such exemplary embodiments can be implemented in various devices, systems, and methods.

### BRIEF DESCRIPTION OF THE DRAWINGS

FIG. 1 is a stack diagram illustrating a bottom electrode on a substrate according to some aspects.

FIG. 2 is a stack diagram illustrating a first transport layer, also called a bottom transport layer, on the stack illustrated in FIG. 1 according to some aspects.

FIG. 3 is a stack diagram illustrating a first colloidal quantum dot (CQD) layer on the stack illustrated in FIG. 2 according to some aspects.

FIG. 4 is a stack diagram illustrating a second CQD layer partially deposited on the stack illustrated in FIG. 2 according to some aspects.

FIG. 5 is a stack diagram illustrating the second CQD layer being thickened via the addition of additional material according to some aspects.

FIG. 6 is a stack diagram illustrating the second CQD layer, also called the intrinsic layer, fully deposited on the stack illustrated in FIG. 2 according to some aspects.

FIG. 7 is a stack diagram illustrating a third CQD layer on the stack illustrated in FIG. 6 according to some aspects.

FIG. 8 is a stack diagram illustrating a fourth CQD layer on the stack illustrated in FIG. 7 according to some aspects.

FIG. 9 is a stack diagram illustrating a second transport layer, also called a top transport layer, on the stack illustrated in FIG. 8 according to some aspects.

FIG. 10 is a stack diagram illustrating a phototransistor that has a top electrode on the stack illustrated in FIG. 9 according to some aspects.

FIG. 11 is a high-level circuit diagram illustrating the phototransistor of FIG. 10 used as a light sensor in a circuit according to some aspects.

FIG. 12 is a circuit diagram illustrating a phototransistor without a top transport layer or a bottom transport layer but otherwise similar to the phototransistor of FIG. 10 according to some aspects.

FIG. 13 is a diagram illustrating a phototransistor without a top transport layer but otherwise similar to the phototransistor of FIG. 10 according to some aspects.

FIG. 14 is a diagram illustrating a phototransistor without a bottom transport layer but otherwise similar to the phototransistor of FIG. 10 according to some aspects.

FIG. 15 is a diagram illustrating a photodiode with a bottom transport layer and a top transport layer that is similar to the phototransistor of FIG. 10 without the fourth CQD layer according to some aspects.

FIG. 16 is a diagram illustrating a photodiode without a top transport layer but otherwise similar to the photodiode of FIG. 15 according to some aspects.

FIG. 17 is a diagram illustrating a photodiode without a bottom transport layer but otherwise similar to the photodiode of FIG. 15 according to some aspects.

FIG. 18 is a diagram illustrating a photodiode without a top transport layer or a bottom transport layer but otherwise similar to the photodiode of FIG. 15 according to some aspects.

FIG. 19 is a diagram illustrating a phototransistor on a substrate with an integrated bottom electrode but otherwise similar to the phototransistor of FIG. 12 according to some aspects.

FIG. 20 is a diagram illustrating the top surface of a read out integrated circuit (ROIC) according to some aspects.

FIG. 21 is a diagram illustrating light sensors such as those illustrated in FIGS. 10-19 in a focal plane array on the ROIC of FIG. 20 according to some aspects.

FIG. 22 is a high-level flow diagram illustrating a process for depositing a CQD layer and then doping the CQD layer according to some aspects.

FIG. 23 is a high-level flow diagram illustrating a process for constructing a doped layer of nanoparticles directly on top of a substrate or less diffusive layers, such as metals.

FIG. 24 is a high-level flow diagram illustrating a method for a light sensing structure and device using CQDs according to some aspects.

FIG. 25 is a high-level flow diagram illustrating a process for using HgTe CQDs to produce a phototransistor according to some aspects.

FIG. 26 is a stack diagram illustrating a bottom electrode on a substrate according to some aspects.

FIG. 27 is a stack diagram illustrating a polysilicon (poly-Si) layer on the stack illustrated in FIG. 26 according to some aspects.

FIG. 28 is a stack diagram illustrating a N-type metal oxide layer on the stack illustrated in FIG. 27 according to some aspects.

FIG. 29 is a stack diagram illustrating a P-type CQD layer on the stack illustrated in FIG. 28 according to some aspects.

FIG. 30 is a stack diagram illustrating a top electrode on the stack illustrated in FIG. 29 according to some aspects.

FIG. 31 is a stack diagram illustrating a N-type metal oxide layer on the stack illustrated in FIG. 26 according to some aspects.

FIG. 32 is a stack diagram illustrating a P-type CQD layer on the stack illustrated in FIG. 31 according to some aspects.

FIG. 33 is a stack diagram illustrating a N-type or intrinsic CQD layer on the stack illustrated in FIG. 32 according to some aspects.

FIG. 34 is a stack diagram illustrating a top electrode on the stack illustrated in FIG. 33 according to some aspects.

FIG. 35 is a high-level flow diagram illustrating a process for constructing an infrared light sensing PNP bipolar junction transistor (BJT) such as the PNP BJT of FIG. 30 according to some aspects.

FIG. 36 is a high-level flow diagram illustrating a process for constructing an infrared light sensing NPN BJT such as the NPN BJT of FIG. 34 according to some aspects.

FIG. 37 is a high-level flow diagram illustrating a process for constructing an infrared image sensor that uses BJTs as a sensor array according to some aspects.

Throughout the description, similar reference numbers may be used to identify similar elements.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment”, “an embodiment”, or similar language means that a particular feature, structure, or characteristic described in connection with the indicated embodiment is included in at least one embodiment of the present invention. Thus, the phrases “in one embodiment”, “in an embodiment”, and similar language throughout this specification may, but do not necessarily, all refer to the same embodiment.

Quantum dot (QD) photodetectors are principally based on the control of the bandgap through quantum confinement, which allows for the selection of detectable wavelengths of light. This has been well utilized in many small band gap systems, including mercury telluride, cadmium telluride, silver selenide, lead selenide, lead sulfide, etc., to make devices sensitive to wavelengths across the infrared spectrum.

In order to improve device performance, internal electric fields generated by the presence of dopants, or the oxidation/reduction of the dots have been applied. This can be accomplished through the chemical treatment of quantum dots in a layer-wise fashion, and can further improve device performance by exchanging the original organic ligands with considerably shorter inorganic ones, enhancing interdot conduction. Furthermore, cation exchange methods have been demonstrated as a way to create heavily doped QD layers.

Of note, the devices in literature thus far, in particular those of the photodiode variety, utilize a single element production process. The devices are built with the transparent electrodes on the bottom of a device stack. Most transparent electrode layers require a thermal annealing process, which would destroy the QD confinement effects, for optimal transmissivity. Phototransistor devices have shown promise by introducing a photocurrent gain, which would improve device performance. Phototransistor devices in literature have been photoconductive in nature, and utilize a field effect analogous to MOSFET devices. As a result, the devices have been planar, and built as three terminal devices.

Furthermore, it is understood that an electron transport layer would increase the performance of optoelectronic QD devices by removing excited carriers from the active QD layers, which have short recombinative carrier lifetimes. Matching the conduction bands of QD band structures with that of the electron transport layers would be an important factor.

In the past, infrared imagers have been produced using light sensors that have been produced using wafer grown materials, which are expensive. Devices based on colloidal quantum dots (CQDs) have been proposed. Some of the devices are lateral phototransistors that have emitter and collector electrodes on an underlying substrate and quantum dot layers deposited over the substrate, emitter electrode, and collector electrode. Some of the light sensors are vertical devices that have quantum dot layers between a top electrode and a bottom electrode. Those vertical devices are largely based on the quantum dot layer becoming conductive on exposure to light of the appropriate frequency.

The optoelectronic devices disclosed here are photon detectors including PIN photodiodes and PINP/NIPN phototransistors that are vertical structures. The PIN photodiodes act as current sources when exposed to light absorbed by an intrinsic CQD layer. The phototransistors are similar in that an intrinsic layer in a PIN arrangement can produce a current, however the phototransistors may also amplify that current. The result is that the disclosed photodiodes and phototransistors are more sensitive than other CQD based structures while having lower dark current. As such, the disclosed devices may operate at higher temperatures than other CQD based photon detectors.

The devices presented offer improvements over the past techniques, particularly in their construction. While single element devices are applicable in photovoltaic systems, they present an issue when moving towards photodetectors. For high resolution detectors, requiring high pixel densities, technologies to bond substrates and sensor devices to one another are both costly and prohibitively difficult. Therefore, the processes presented take a “bottom-up” approach, where the light collecting side of the detector is constructed last. This makes the sensor easily applicable to imaging devices constructed beneath the active layers. In addition, with limited patterning and lithography steps, these devices can be produced quickly and more economically than other alternatives.

The phototransistor presented utilizes the present ability to dope QD layers to build junctions analogous to BJT devices. It is therefore able to provide a significant current gain through an emitter-base junction, as opposed to other devices which have thus far been limited to ambipolar field effect transistors. In addition, the internal electric fields formed by doping the QD layers as they are constructed enables the vertical construction of the phototransistor. This allows for a much higher pixel density over planar devices, since the device footprint is determined only by the bottom electrode.

The devices require an electrode contacting the previous QD layers. An electrode can be deposited and make ohmic contact with the previous QD layers with limited thermal processing. This can be found in a variety of materials, such as graphene, carbon nanotubes, nanosheets of conductive metals (e.g., nanosheet gold), metal nanowire meshes, and thin unannealed layers of certain metal oxides. Overall, as deposited, the electrodes should be primarily transmissive in the spectrum of interest, and sufficiently conductive as to not impair device performance. The devices in literature at present do not meet all of these requirements.

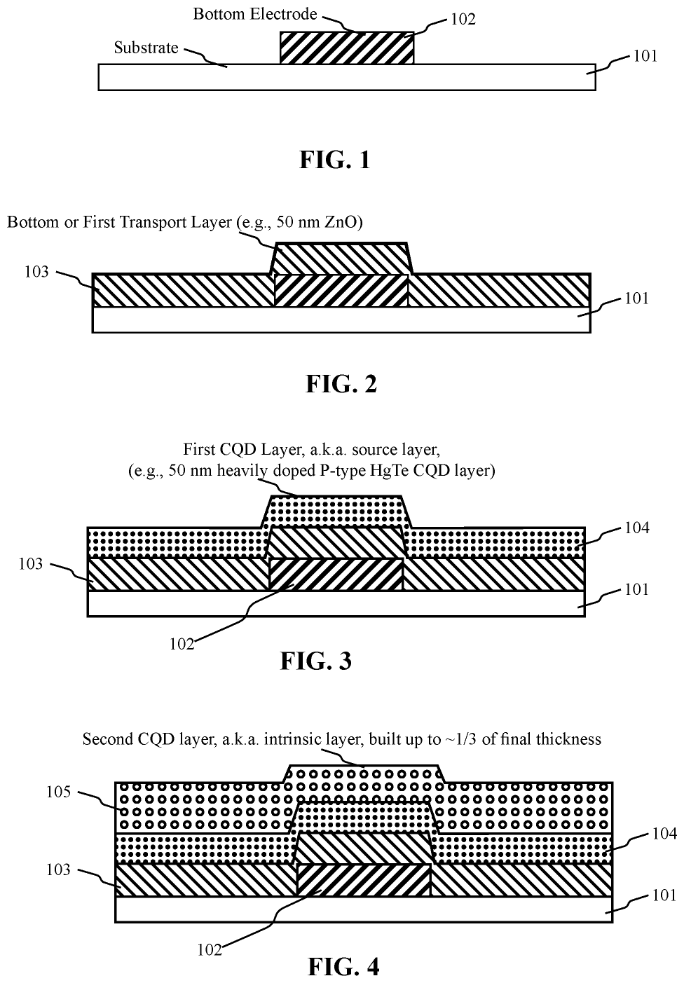

FIGS. 1-10 illustrate a vertical phototransistor structure being built up. The phototransistor can be a PINP device or a NIPN device. The devices include CQD layers that can be P-type or N-type. The layers may be deposited via one or more drop casting steps. For example, mercury telluride (HgTe) CQD layers can be built up by one or more prop casting steps using a HgTe CQD solution. Undoped HgTe CQD layers are naturally P-type. P-type doping a HgTe CQD layer results in a highly P-type HgTe CQD layer. A highly P-type mercury telluride (HgTe) CQD layer can be deposited by depositing HgTe CQDs followed by a cation exchange involving silver telluride (Ag₂Te) quantum dots and a treatment of mercury chloride (HgCl₂). The cation exchange operation may be repeated between drop castings as a layer is built up. The concentration of Ag₂Te controls how strongly P-type the HgTe is because of the speed of the reaction. Due to the speed of the reaction, the residency time of the Ag₂Te and quantum dot precursor solution over the HgTe layer has thus far in experimentation been far less important than the Ag₂Te concentration. N-type HgTe CQD layers can be produced using an HgCl₂ treatment that does not include Ag or Ag₂Te. More highly N-type HgTe CQD layers can be produced using higher concentrations of mercury chloride between drop casting depositions of HgTe CQDs to gain a heavily N-type characteristic.

FIG. 1 is a stack diagram illustrating a bottom electrode 102 on a substrate 101 according to some aspects. The bottom electrode can be aluminum, copper, indium tin oxide (ITO) or some other conductive material. The bottom electrode can be formed using standard photolithography techniques as are well known in the art of semiconductor manufacturing.

FIG. 2 is a stack diagram illustrating a first transport layer 103, also called a bottom transport layer, on the stack illustrated in FIG. 1 according to some aspects. For a PINP phototransistor, the first transport layer 103 is an electron transport layer. Materials such as metal chalcogens or indium phosphide can be used as an electron transport layer. A 50 nm thick zinc oxide (ZnO) layer is an example of an electron transport layer. For a NIPN phototransistor, the first transport layer 103 is a hole transport layer. Materials such as titanium dioxide and molybdenum trioxide can be used as a hole transport layer. A 50 nm thick titanium dioxide layer is an example of a hole transport layer. The transport layer can be deposited using sputtering, physical vapor deposition (PVD), chemical vapor deposition (CVD), or chemical bath deposition techniques.

FIG. 3 is a stack diagram illustrating a first colloidal quantum dot (CQD) layer 104 on the stack illustrated in FIG. 2 according to some aspects. The first CQD layer can be a mercury telluride (HgTe) CQD layer.

For a PINP phototransistor, the first CQD layer is a P-type layer. A P-type first CQD layer can be deposited by doping the first CQD layer. As discussed above, a HgTe CQD layer can be doped P-type following a cation exchange involving silver telluride quantum dots and a treatment of mercury chloride. Other infrared sensitive quantum dots may be applicable, so long as they can be modified for sufficient P-type character. For a PINP phototransistor, this layer can be a 50 nm layer, and acts as the collector in the phototransistor.

Doping refers to a technique of changing the carrier concentration of a material such as CQDs. For example, a HgTe CQD layer is naturally slightly P-type. A treatment using a quantum dot precursor (e.g., HgCl₂, PbCl₂ or InCl₃) can change the carrier concentration of HgTe CQDs. Treatment using a solution the includes the quantum dot precursor and a cation (e.g., Ag) can make the HgTe CQDs more strongly P-type with even more concentrated solutions of cations making the HgTe CQDs even more strongly P-type. Here, the concentration of majority carriers (holes) is positively correlated with the cation concentration. Treatment using a solution that includes only the quantum dot precursor can make the HgTe CQDs N-type with more concentrated solutions making the HgTe CQDs more strongly N-type. Here, the concentration of majority carriers (electrons) is positively correlated with the quantum dot precursor concentration.

For a NIPN phototransistor, the first CQD layer is a N-type layer. A N-type first CQD layer can be deposited by doping the first CQD layer. For example, a N-type HgTe CQD layer can be deposited by depositing a HgTe CQD layer that is doped by treating it using a concentration of mercury chloride (HgCl₂) between drop casting depositions to gain a heavily N-type characteristic. The factor governing the level of N-type doping is the concentration of the mercury chloride. HgTe CQDs are naturally slightly P-type. At one concentration level of HgCl₂ the HgTe CQDs become intrinsic, at higher concentration levels of HgCl₂, the HgTe CQDs become increasingly N-type.

FIG. 4 is a stack diagram illustrating a second CQD layer 105 partially deposited on the stack illustrated in FIG. 2 according to some aspects. The second CQD layer's primary purpose is to act as the primary photoactive region and is placed well within the device's internal electric field. In the illustrated example, the second layer 105 becomes the intrinsic layer of the PIN, PINP, and NIPN devices. The intrinsic layer can also be called the absorption layer. The primary photo active region, or absorption layer, is where the majority of photons should be absorbed in order to generate the base current within the transistor. Because of this, it should be the thickest layer within the device, provided trap states can be kept limited to promote charge separation and transfer. This layer can be built up by a series of drop casting steps, spaced between treatments of mercury chloride, whose concentration is controlled to make the layer intrinsic. Provided trap states are kept limited within this layer, it should be thicker to prioritize photo absorption. For example, a 300 nm thick intrinsic HgTe CQD layer can be built up. The second CQD layer may be the absorption layer or the intrinsic layer. PINP and NINP phototransistors both have an intrinsic layer. FIG. 4 illustrates a point approximately one third of the way to producing the entire intrinsic layer.

FIG. 5 is a stack diagram illustrating the second CQD layer 105 being thickened via the addition of additional material according to some aspects. Further drop casting steps and mercury chloride treatments have built up the intrinsic layer 105 to approximately two thirds its final thickness.

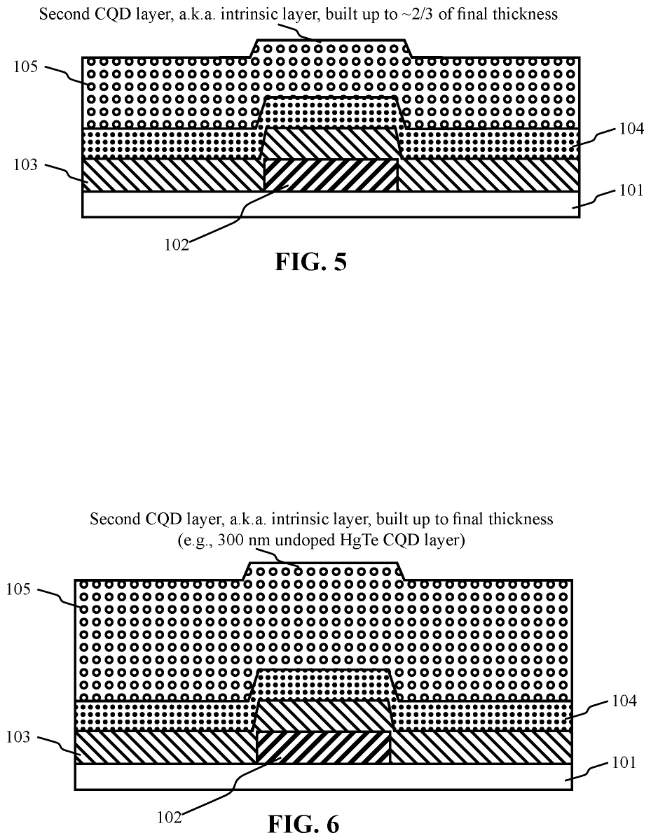

FIG. 6 is a stack diagram illustrating the second CQD layer 105, also called the intrinsic layer, fully deposited on the stack illustrated in FIG. 2 according to some aspects. Further drop casting steps and mercury chloride treatments have built up the intrinsic layer 105 to its final thickness (e.g., 300 nm).

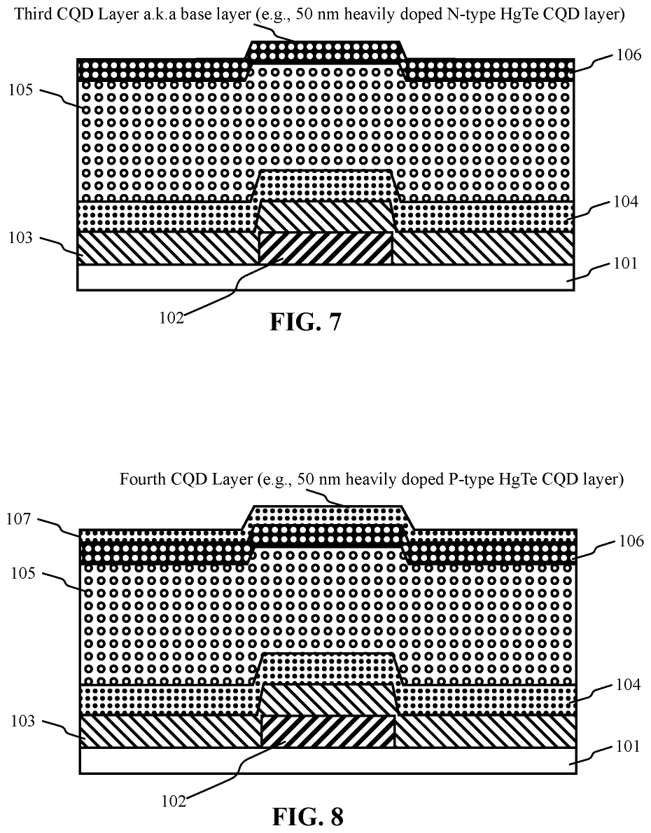

FIG. 7 is a stack diagram illustrating a third CQD layer 106 on the stack illustrated in FIG. 6 according to some aspects. Depositing the third CQD layer produces a PIN junction. For a PINP phototransistor, the third CQD layer is N-type. A N-type HgTe layer can be deposited by using a high concentration of mercury chloride between drop casting depositions to gain a heavily N-type characteristic. For a NIPN phototransistor, the third CQD layer is P-type. For example, the third CQD layer 106 can be a highly P-type HgTe layer that can be deposited using a cation exchange involving silver telluride quantum dots and a treatment of mercury chloride as the layer is produced. In the example illustrated in FIG. 7, the third CQD layer 106 is 50 nm thick.

FIG. 8 is a stack diagram illustrating a fourth CQD layer 107 on the stack illustrated in FIG. 7 according to some aspects. For a PINP phototransistor, the fourth CQD layer 107 is P-type. For example, the fourth CQD layer can be a highly P-type HgTe layer that is deposited using a cation exchange involving silver telluride quantum dots and a treatment of mercury chloride as the layer is produced. For a NIPN phototransistor, the fourth CQD layer is N-type. A N-type HgTe layer can be deposited by using a high concentration of mercury chloride between drop casting depositions to gain a heavily N-type characteristic. In the example illustrated in FIG. 8, the fourth CQD layer 107 is 50 nm thick.

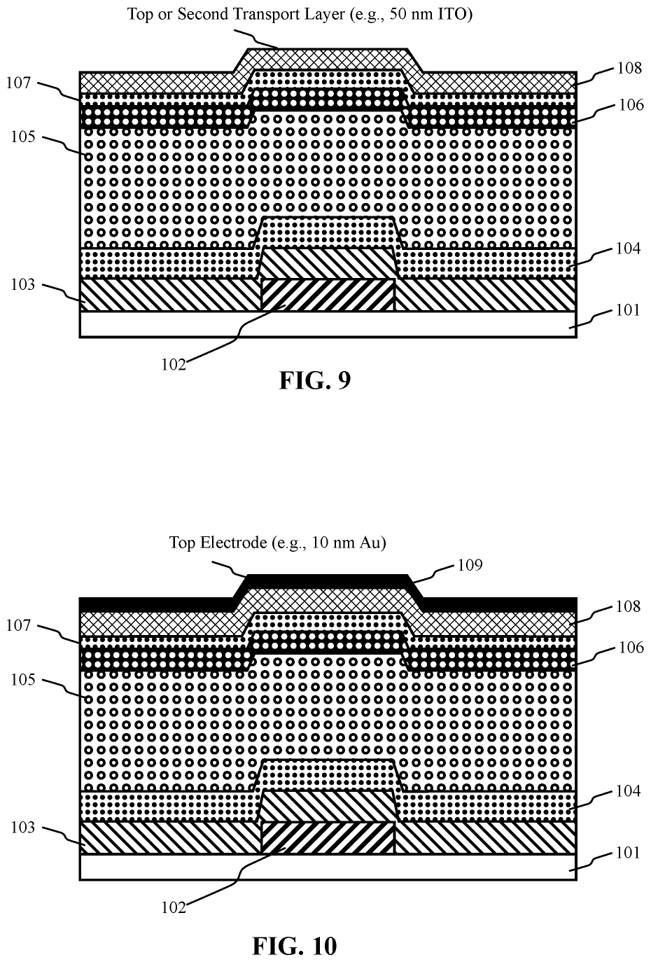

FIG. 9 is a stack diagram illustrating a second transport layer 108, also called a top transport layer, on the stack illustrated in FIG. 8 according to some aspects. For a PINP phototransistor, the second transport layer 108 is a hole transport layer. For a NINP phototransistor, the second transport layer 108 is an electron transport layer. Many devices will omit the top transport layer.

FIG. 10 is a stack diagram illustrating a phototransistor that has a top electrode 109 on the stack illustrated in FIG. 9 according to some aspects. Depositing the top electrode is highly dependent on the material employed. For graphene technologies, the device would be coated in a sheet of graphene following the etching of its copper foil growth substrate. For carbon nanotubes, soft lithography stamps can be used, and the use of aerosol printing has been demonstrated. Metal sheets with thicknesses on the order of atoms can be applied using electron beam deposition, or the simple chemical deposition of nanowire meshes can be employed as well. In the example of FIG. 10, a gold nanosheet 10 nm thick is applied. Indium tin oxide (ITO) may be used as a top electrode. At least 50% of normally incident IR light may pass through an ITO transport layer. Damage to underlying CQD layers can be avoided by depositing the top electrode using a low temperature process such as vapor deposition, electron beam deposition, chemical deposition or aerosol deposition. The top electrode can be a common electrode for a number of underlying phototransistors or photodiodes. Here, a common electrode is an electrically continuous layer that numerous devices use as an electrode. For example, an unpatterned ITO layer can be the collector electrodes for an array of phototransistors.

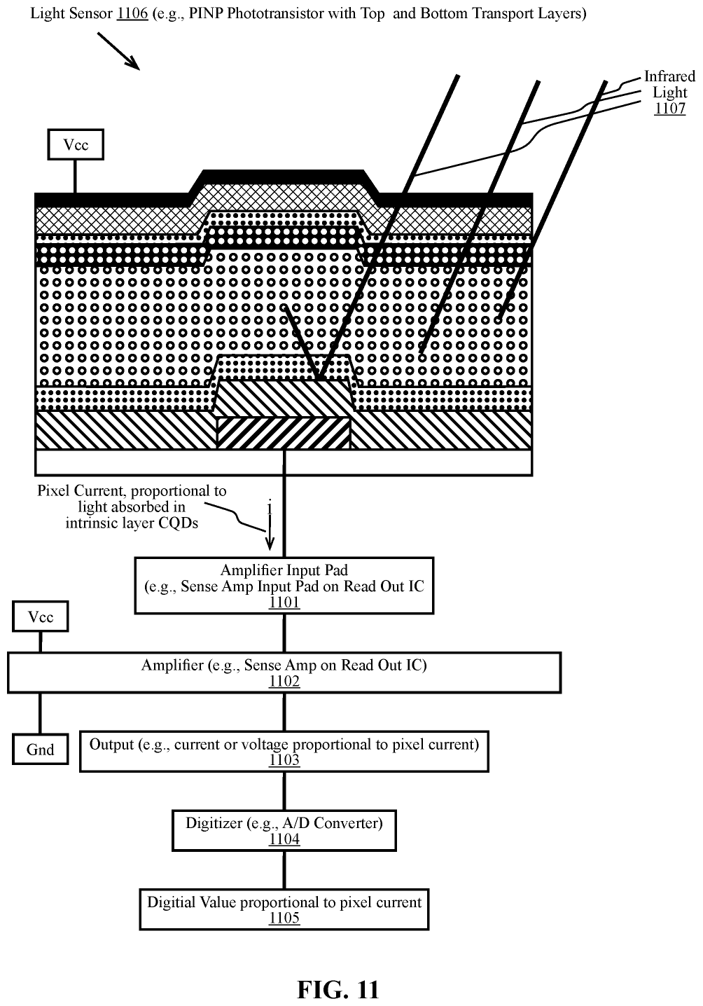

FIG. 11 is a high-level circuit diagram illustrating the phototransistor of FIG. 10 used as a photon detector in a circuit according to some aspects. A pixel current is produced when infrared light 1107 passes through the top of the device and is absorbed in the second CQD layer 105. Some of the infrared light may pass entirely through the second CQD layer 105. For this reason, the first transport layer 103 can be a back side reflector. The back side reflector can be a material that reflects light back into the absorption layer. For example, a ZnO transport layer can reflect 45% or more of IR light in many wavelength ranges. Photons reflected from the first transport layer may be absorbed in the second CQD layer 105. The pixel current is proportional to the number of photons absorbed in the second layer 105. The photon detectors may be formed over a read out integrated circuit (ROIC) that has amplifier input pads, amplifiers, and digitizers. The pixel current can pass from the bottom electrode of the photon detector to an amplifier input pad 1101. The amplifier input pad 1101 can be an input to an amplifier 1102 that produces on output 1103. The output can be a voltage or a current, based on the specific type of amplifier used. The output can be passed to a digitizer 1104 that produces a digital value 1105 that is proportional to the pixel current.

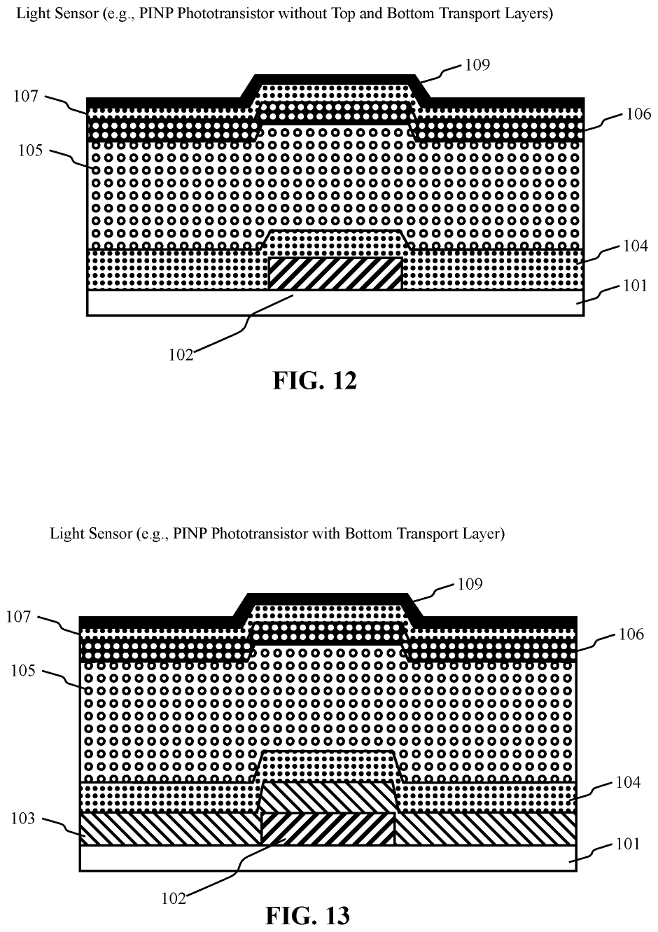

FIG. 12 is a circuit diagram illustrating a phototransistor without a top transport layer or a bottom transport layer but otherwise similar to the phototransistor of FIG. 10 according to some aspects. The phototransistor illustrated in FIG. 10 includes many layers. The steps for depositing some of those layers may be omitted such that a different device is produced. FIG. 12 illustrates a phototransistor on a substrate 101 and having a bottom electrode 102, a first CQD layer 104, a second CQD layer 105, a third CQD layer 106, a fourth CQD layer 107, and a top electrode 109.

FIG. 13 is a diagram illustrating a phototransistor without a top transport layer but otherwise similar to the phototransistor of FIG. 10 according to some aspects. FIG. 13 illustrates a phototransistor on a substrate 101 and having a bottom electrode 102, a first transport layer 103, a first CQD layer 104, a second CQD layer 105, a third CQD layer 106, a fourth CQD layer 107, and a top electrode 109.

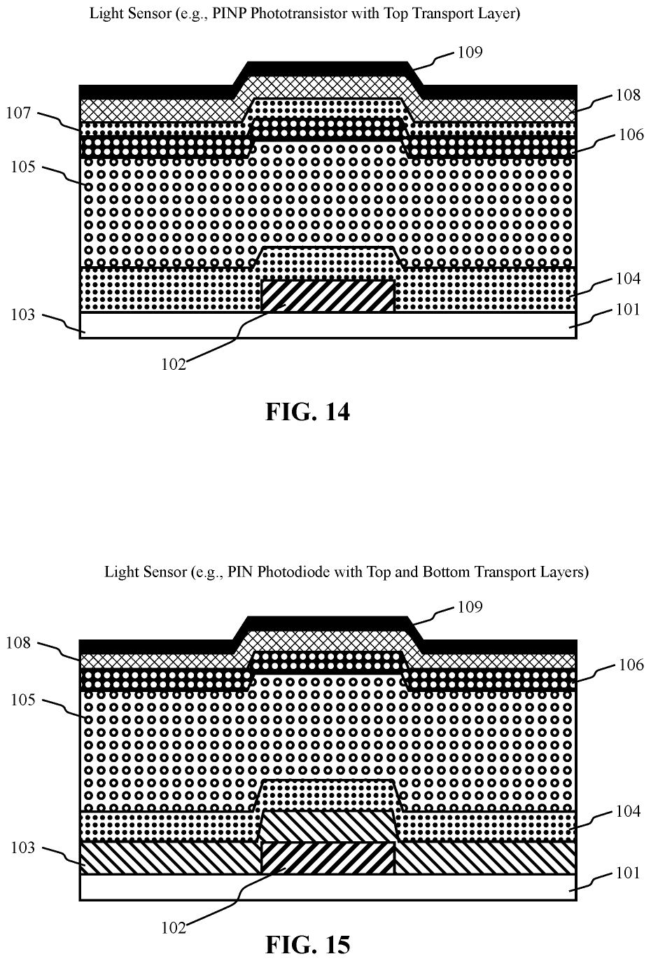

FIG. 14 is a diagram illustrating a phototransistor without a bottom transport layer but otherwise similar to the phototransistor of FIG. 10 according to some aspects. FIG. 14 illustrates a phototransistor on a substrate 101 and having a bottom electrode 102, a first CQD layer 104, a second CQD layer 105, a third CQD layer 106, a fourth CQD layer 107, a second transport layer 108, and a top electrode 109.

FIG. 15 is a diagram illustrating a photodiode with a bottom transport layer and a top transport layer that is similar to the phototransistor of FIG. 10 without the fourth CQD layer according to some aspects. Here, it is observed that omitting the steps that produce the fourth CQD layer results in producing photodiodes. FIG. 15 illustrates a photodiode on a substrate 101 and having a bottom electrode 102, a first transport layer 103, a first CQD layer 104, a second CQD layer 105, a third CQD layer 106, a second transport layer 108, and a top electrode 109.

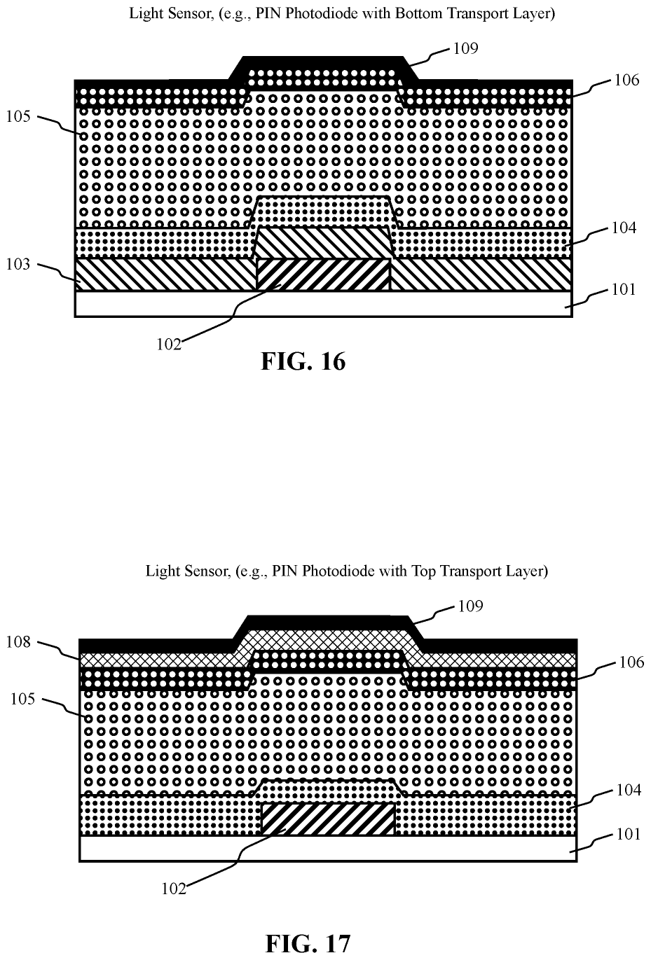

FIG. 16 is a diagram illustrating a photodiode without a top transport layer but otherwise similar to the photodiode of FIG. 15 according to some aspects. FIG. 16 illustrates a photodiode on a substrate 101 and having a bottom electrode 102, a first transport layer 103, a first CQD layer 104, a second CQD layer 105, a third CQD layer 106, and a top electrode 109.

FIG. 17 is a diagram illustrating a photodiode without a bottom transport layer but otherwise similar to the photodiode of FIG. 15 according to some aspects. FIG. 17 illustrates a photodiode on a substrate 101 and having a bottom electrode 102, a first CQD layer 104, a second CQD layer 105, a third CQD layer 106, a second transport layer 108, and a top electrode 109.

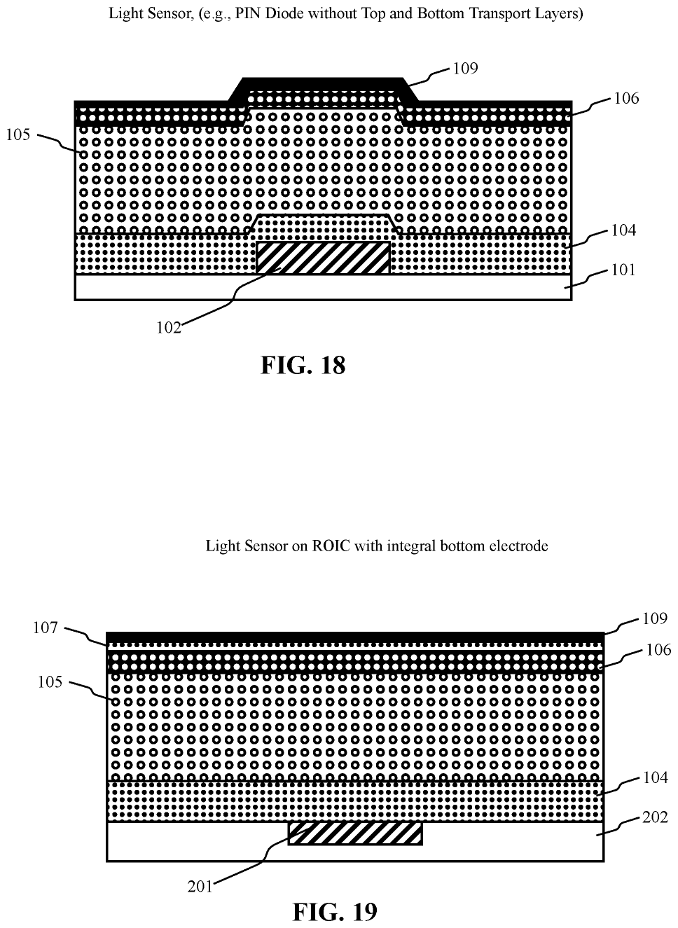

FIG. 18 is a diagram illustrating a photodiode without a top transport layer or a bottom transport layer but otherwise similar to the photodiode of FIG. 15 according to some aspects. FIG. 18 illustrates a photodiode on a substrate 101 and having a bottom electrode 102, a first CQD layer 104, a second CQD layer 105, a third CQD layer 106, and a top electrode 109.

FIG. 19 is a diagram illustrating a phototransistor on a substrate with an integrated bottom electrode but otherwise similar to the phototransistor of FIG. 12 according to some aspects. The substrate can be a ROIC 202. In fact, one of the advantages of light sensors formed by depositing layers of CQDs is that a focal plane array of light sensors can easily be produced directly on the ROIC by drop casting (or spin casting, etc.) layers of CQDs directly on the ROIC. Furthermore, the only layer that may have to be patterned is the bottom electrode. The rest of the layers may be unpatterned. Here, an unpatterned layer is a layer for which no steps, such as photolithography, have been taken to pattern the layer. A layer can stay unpatterned when it is initially unpatterned and remains unpatterned after subsequent processing steps. The substrate can be a ROIC 202 that has input pads 201 on its top surface. The input pad 201 can be used as the bottom electrode of a phototransistor or photodiode. As such, the ROIC input pads are bottom electrodes that are integrated into the substrate.

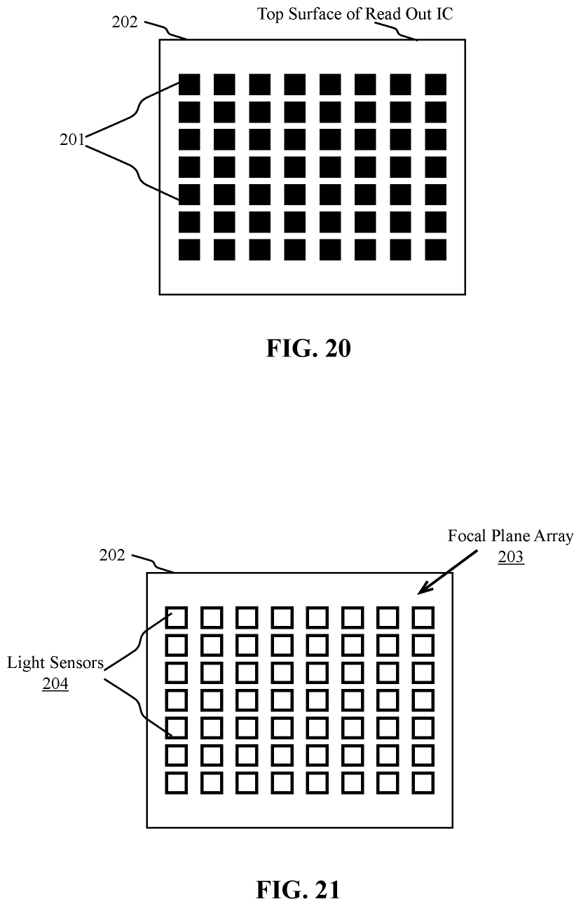

FIG. 20 is a diagram illustrating the top surface of a ROIC 202 according to some aspects. The ROIC has an array of input pads 201 that can be used as the bottom electrodes of light sensors.

FIG. 21 is a diagram illustrating light sensors 204 such as those illustrated in FIGS. 10-19 in a focal plane array 203 on the ROIC of FIG. 20 according to some aspects. The focal plane array 203 can be formed by depositing layers of material, as discussed above, directly on the ROIC. For example, a focal plane array of phototransistors may be produced by depositing a first CQD layer 104, a second CQD layer 105, a third CQD layer 106, a fourth CQD layer 107, and a top electrode 109. All of the layers may be unpatterned. In some embodiments, the top electrode may be printed on with a pattern.

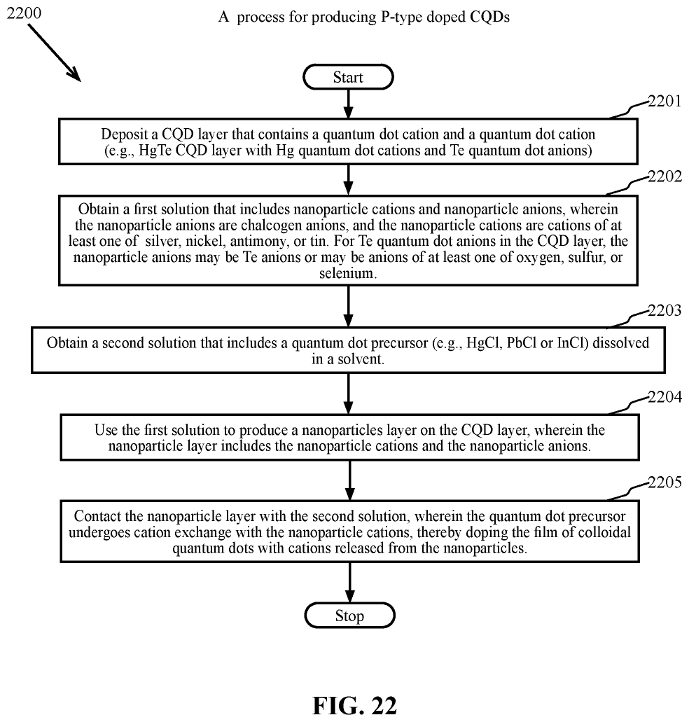

FIG. 22 is a high-level flow diagram illustrating a process for depositing a doped CQD layer 2200 by depositing a CQD layer and then doping the CQD layer according to some aspects. After the start, at block 2201 the process can include depositing a CQD layer that contains a quantum dot cation and a quantum dot cation. For example, a HgTe CQD layer has Hg quantum dot cations and Te quantum dot anions. At block 2202, the process can include obtaining a first solution that includes nanoparticle cations and nanoparticle anions, wherein the nanoparticle anions are chalcogen anions, and the nanoparticle cations are cations of at least one of silver, nickel, antimony, or tin. For Te quantum dot anions in the CQD layer, the nanoparticle anions may be Te anions or may be anions of at least one of oxygen, sulfur, or selenium. At block 2203, the process can include obtaining a second solution that includes a quantum dot precursor (e.g., HgCl₂, PbCl₂ or InCl₃) dissolved in a solvent. The solvent can be polar or protic solvents, such as water, methanol, propanol, or ethanol. The solvent can be a mixture of or include polar or protic solvents, such as water, methanol, propanol, or ethanol. At block 2204, the process can include using the first solution to produce a nanoparticle layer on the CQD layer, wherein the nanoparticle layer includes the nanoparticle cations and the nanoparticle anions. At block 2205, the process can include contacting the nanoparticle layer with the second solution, wherein the quantum dot precursor undergoes cation exchange with the nanoparticle cations, thereby doping the film of colloidal quantum dots with cations released from the nanoparticles.

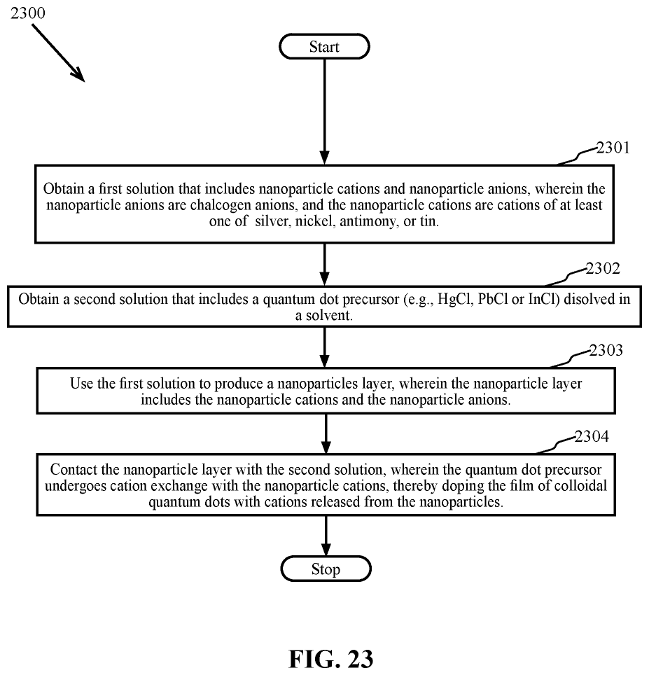

FIG. 23 is a high-level flow diagram illustrating a process for constructing a doped layer of nanoparticles directly on top of a substrate or less diffusive layers, such as metals. After the start, at block 2301 the process can include obtaining a first solution that includes nanoparticle cations and nanoparticle anions, wherein the nanoparticle anions are chalcogen anions, and the nanoparticle cations are cations of at least one of silver, nickel, antimony, or tin. At block 2302, the process can include obtaining a second solution that includes a quantum dot precursor (e.g., HgCl₂) dissolved in a solvent. At block 2303, the process can include using the first solution to produce a nanoparticle layer, wherein the nanoparticle layer includes the nanoparticle cations and the nanoparticle anions. At block 2304, the process can include contacting the nanoparticle layer with the second solution, wherein the quantum dot precursor undergoes cation exchange with the nanoparticle cations, thereby doping the film of colloidal quantum dots with cations released from the nanoparticles. Here, the doped layer is the layer being deposited.

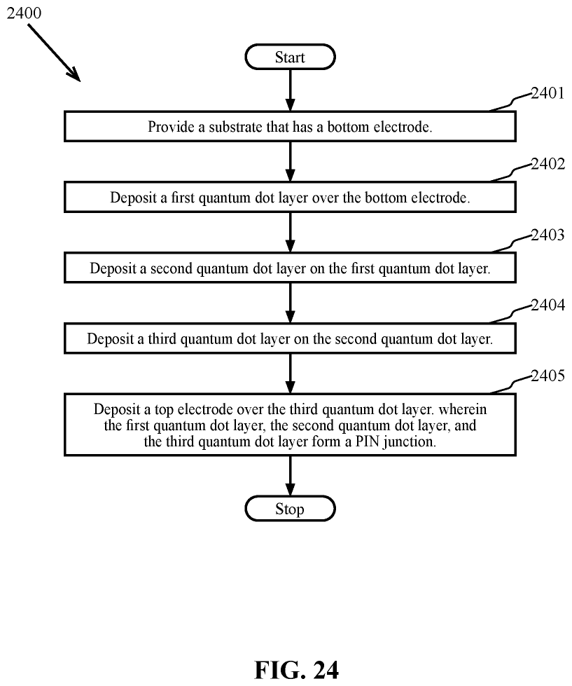

FIG. 24 is a high-level flow diagram illustrating a method for a light sensing structure and device using CQDs 2400 according to some aspects. After the start, at block 2401 the process can include providing a substrate that has a bottom electrode. At block 2402 the process can include depositing a first quantum dot layer over the bottom electrode. At block 2403 the process can include depositing a second quantum dot layer on the first quantum dot layer. At block 2404 the process can include depositing a third quantum dot layer on the second quantum dot layer. At block 2405 the process can include depositing a top electrode over the third quantum dot layer, wherein the first quantum dot layer, the second quantum dot layer, and the third quantum dot layer form a PIN junction.

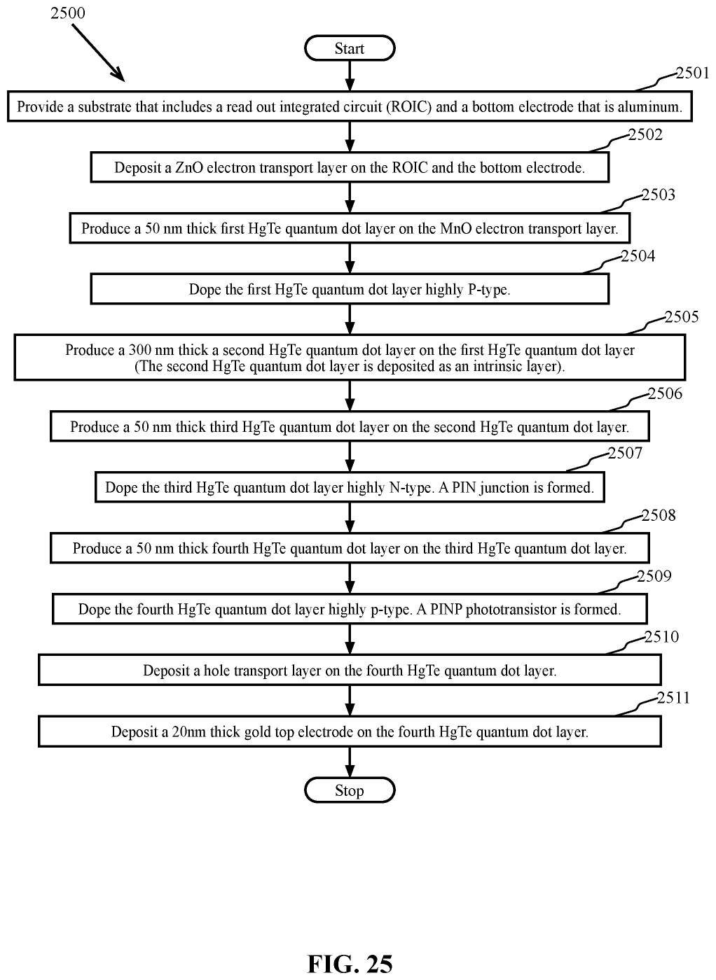

FIG. 25 is a high-level flow diagram illustrating a process for using HgTe CQDs to produce a phototransistor 2500 according to some aspects. After the start, at block 2501 the process can include providing a substrate that includes a read out integrated circuit (ROIC) and a bottom electrode that is aluminum. At block 2502 the process can include depositing a ZnO electron transport layer on the ROIC and the bottom electrode. At block 2503 the process can include producing a 50 nm thick first HgTe quantum dot layer on the MnO electron transport layer. At block 2504 the process can include doping the first HgTe quantum dot layer highly P-type. At block 2505 the process can include producing a 300 nm thick second HgTe quantum dot layer on the first HgTe quantum dot layer. The second HgTe quantum dot layer is deposited as an intrinsic layer. Intrinsic layers are neither P-type or N-type. At block 2506 the process can include producing a 50 nm thick third HgTe quantum dot layer on the second HgTe quantum dot layer. At block 2507 the process can include doping the third HgTe quantum dot layer highly N-type. A PIN junction is formed. At block 2508 the process can include producing a 50 nm thick fourth HgTe quantum dot layer on the third HgTe quantum dot layer. At block 2509 the process can include doping the fourth HgTe quantum dot layer highly P-type. A PINP phototransistor is formed. At block 2510 the process can include depositing a hole transport layer on the fourth HgTe quantum dot layer. At block 2511 the process can include depositing a 20 nm thick gold top electrode on the fourth HgTe quantum dot layer. The phototransistor has layers that are intrinsic, N-type layer, and P-type. In an example, the N-type layer and P-type layers can have majority carriers (electrons or holes) exceeding 10¹⁷ majority carriers per cubic centimeter.

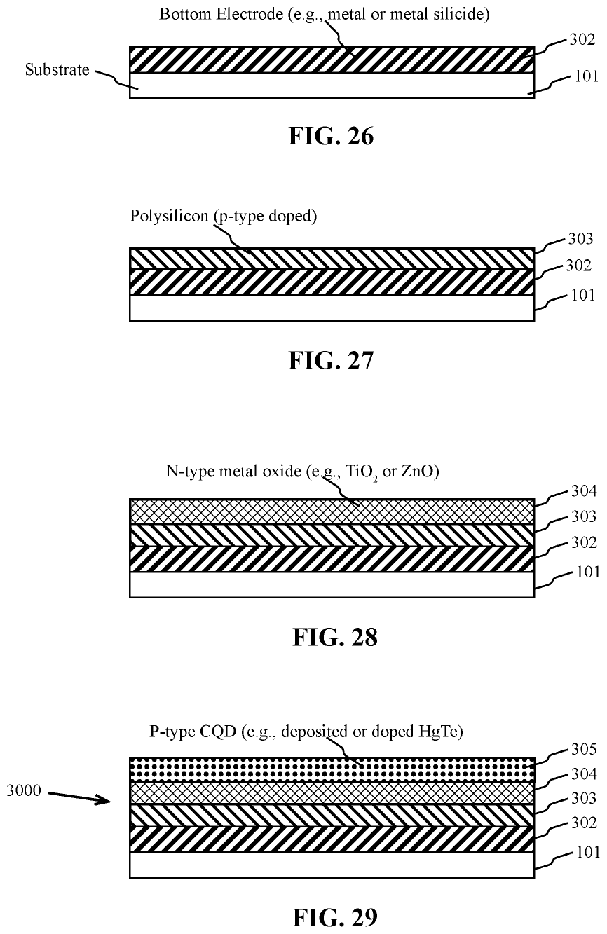

FIGS. 26-30 illustrate a stack of various materials deposited over a substrate 101 to thereby produce a PNP bipolar junction transistor (BJT). FIGS. 26 and 31-34 30 illustrate a stack of various materials deposited over a substrate 101 to thereby produce a NPN BJT. Light, such as infrared light, can be absorbed by an active layer of a BJT, thereby freeing charge carriers (e.g., electrons or holes) that may then become a current flowing between the collector and the emitter of the BJT. Those familiar with BJTs will recognize that the active layer is acting as the base of the BJT and that the absorbed photons are creating a base current. Those familiar with BJTs are also aware of numerous techniques and circuits that use BJTs to amplify a base current. In general, the techniques/circuits apply a collector voltage (Vc) to the collector of the BJT and an emitter voltage (Ve) to the emitter of the BJT, thereby creating a bias voltage (Vbias=Vc−Ve). An NPN BJT amplifies the base current when the bias voltage is greater than a threshold voltage that is greater than zero and that is a property of the NPN transistor. A PNP BJT amplifies the base current when the bias voltage is less than a threshold voltage that is less than zero and that is a property of the PNP transistor.

The NPN BJT has a P-type semiconducting layer between two N-type semiconducting layers. The P-type semiconducting layer can be a P-type CQD layer (e.g., doped HgTe) that is an active layer that absorbs photons and produces a photocurrent that is the base current of the BJT.

The PNP BJT has a N-type semiconducting layer between two P-type semiconducting layers. The N-type semiconducting layer can be a N-type metal oxide that is an active layer that absorbs photons and produces a photocurrent that is the base current of the BJT. Titanium oxide (TiO₂) and zinc oxide (ZnO) are examples of metal oxides that may be used as the N-type metal oxide layer of the PNP BJT. The size of HgTe QDs can influence whether the QDs are intrinsically N-type or intrinsically P-type. In general, small HgTe QDs are intrinsically P-type while large HgTe QDs are intrinsically N-type. As such, the size of the QDs can be controlled to thereby control whether they are intrinsically P-type, intrinsically N-type, or intrinsic. “Intrinsic” indicates neither N-type nor P-type. “Intrinsically” indicates “as deposited”. Intrinsically N-type quantum dots have an N-type character as they are deposited and may be doped to thereby become intrinsic, more strongly N-type, or P-type. Intrinsically P-type quantum dots have a P-type character as they are deposited and may be doped to thereby become intrinsic, more strongly P-type, or N-type. The degree to which quantum dots are intrinsically N-type or intrinsically P-type is a process variable that can vary with process changes. As such, processes for producing devices such as BJTs can include metrology steps in which the charge carrier concentrations of the QD layers are measured such that the process can be adjusted to produce QDs with the desired character.

The BJTs described herein may be produced by depositing a stack of layers over a ROIC 202 such that the input pads 201 of the ROIC are the collector electrodes or emitter electrodes of an array of BJTs. The layers of the stack may stay unpatterned. As is well known in semiconductor processing, a layer may be patterned via steps that include photolithographic steps, an etching step, and cleanup steps (e.g., ashing or stripping) that clean up the photolithographic residues. Such patterning steps are expensive and time consuming. Unpatterned layers are layers of material that have not been patterned. Layers that stay or remain unpatterned are layers in completed devices that have not patterned by etching processes or similar processes.

The material stacks discussed herein may be deposited over a ROIC to thereby produce an array of BJTs. The material stacks may stay unpatterned. As such, the layers directly above the ROIC electrodes act as an array of active photosensitive devices such as NPN BJTs or PNP BJTs. In some implementations, the top electrode may be patterned to thereby allow photons to reach the active layer. In other implementations, the top electrode is transparent to the photons of interest such as infrared photons.

FIG. 26 is a stack diagram illustrating a bottom electrode 302 on a substrate 101 according to some aspects. For simplicity, the bottom electrode 302 is illustrated as being unpatterned. In practice, the bottom electrode can be patterned similarly to the bottom electrode 102 of the stacks illustrated in FIGS. 1-19. Such patterning adds cost to the production process. The substrate 110 and the bottom electrode 302 may be the top of a ROIC 202 such that the bottom electrode 302 is an input pad 201 of the ROIC 202.

FIG. 27 is a stack diagram illustrating a polysilicon (poly-Si) layer 303 on the stack illustrated in FIG. 26 according to some aspects. The poly-Si layer 303 can stay unpatterned when the substrate 110 and the bottom electrode 302 are a ROIC 202 and an input pad 201 of the ROIC 202. The chemical vapor deposition (CVD) of poly-Si is typically conducted at high temperatures, which raises concerns about the melting and/or alloying of the metal with the silicon layer being formed above. To address this, refractive metals with high melting points like tungsten may be used, as well as metal silicides like nickel silicide.

FIG. 28 is a stack diagram illustrating a N-type metal oxide layer 304 on the stack illustrated in FIG. 27 according to some aspects. FIG. 29 is a stack diagram illustrating a P-type CQD layer 305 on the stack illustrated in FIG. 28 according to some aspects. To promote charge extraction, the N-type metal oxide layer 304 may be a N-type metal oxides such as TiO₂ and ZnO implemented previously. Aluminum doped zinc oxide (AZO) is another example of an N-type metal oxide. The P-type CQD layer 305 may be a P-type HgTe layer. As discussed above, a P-type HgTe layer may be deposited as a P-type HgTe layer, may be doped P-type after deposition, etc. A P-type CQD layer such as P-type layer 305 may be an intrinsically P-type HgTe layer. A P-type layer may be an intrinsically P-type HgTe layer that has been doped to produce a material that is more strongly P-type. A P-type layer may be an intrinsic HgTe layer that has been doped to produce a material that is P-type. The N-type metal oxide layer 304 and the P-type CQD layer 305 can stay unpatterned when the substrate 110 and the bottom electrode 302 are a ROIC 202 and an input pad 201 of the ROIC 202.

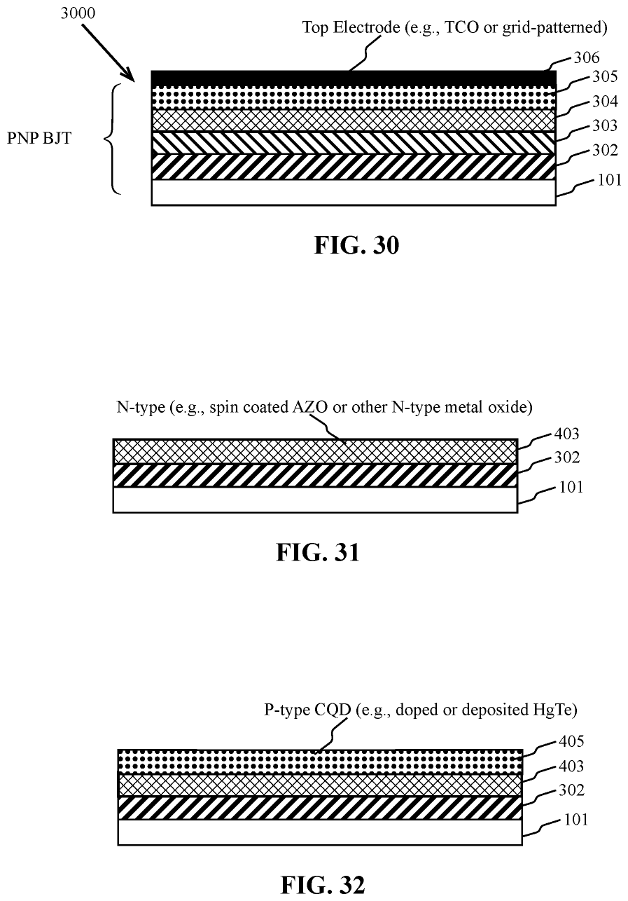

FIG. 30 is a stack diagram illustrating a top electrode 306 on the stack illustrated in FIG. 29 according to some aspects. The top electrode 306 may be a transparent conducting oxide (TCO) such as indium tin oxide (ITO), fluorine doped tin oxide (FTO), niobium doped anatase TiO2 (NTO), doped zinc oxide, etc. The top electrode 306 may be a transparent conducting film (TCF) such as a TCO, carbon nanotube network, graphene, organic polymers, etc. Techniques for fabricating graphene layers that are highly transparent to infrared light are known. Organic polymers that are highly transparent to infrared light may be derivatives of polyacetylene, polyaniline, polypyrrole or polythiophenes. The top electrode 306 can stay unpatterned when the substrate 110 and the bottom electrode 302 are a ROIC 202 and an input pad 201 of the ROIC 202. In some implementations, the top electrode may be patterned to enhance passage of photons to the active layer. The three semiconducting layers 303, 304, 305 form a PNP BJT 3000. The P-type layers 303, 305 are the collector and emitter of the BJT. The top electrode and the bottom electrode are the collector electrode and the emitter electrode of the BJT. The collector is contacting the collector electrode. The emitter electrode is contacting the emitter.

FIGS. 31-34 illustrated the layers of an NPN BJT. It has been demonstrated that following P-type doping of the quantum dots, a rectifying junction is formed between the doped and undoped layers of material. This junction can be integrated into an NPN BJT device by using N-type oxides such as those discussed previously. AZO is available in nanoparticulate spin-coating inks. The aluminum doping acts to further enhance the N-type character of the film. Other nanocrystalline spin-on oxides may be used for this purpose. Combined with the solution processed CQD material, this enables the fabrication of devices which (after initial metallization) may never need to be processed under vacuum conditions, offering a time and cost savings. The metal oxides may alternatively be deposited using conventional methods as well (sputtering, MOCVD, etc.).

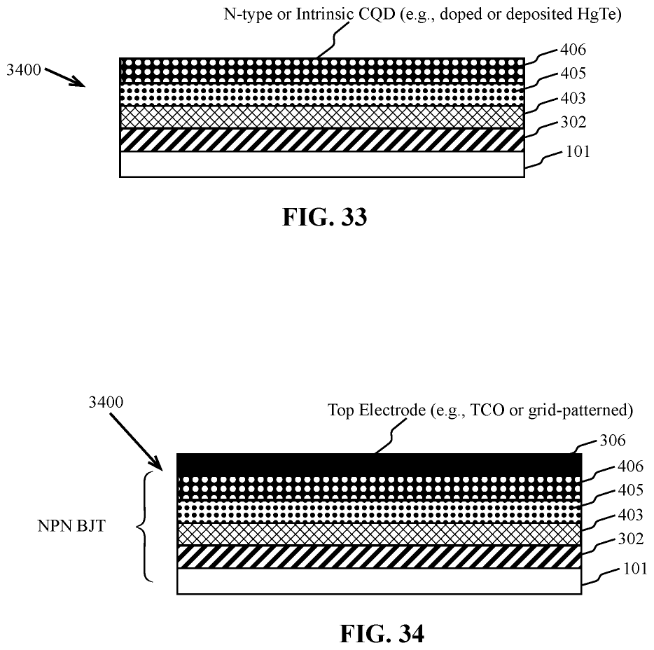

FIG. 31 is a stack diagram illustrating a N-type metal oxide layer 403 on the stack illustrated in FIG. 26 according to some aspects. FIG. 32 is a stack diagram illustrating a P-type CQD layer 405 on the stack illustrated in FIG. 31 according to some aspects. As discussed above, the P-type QD layer 405 can be a HgTe layer that has been doped P-type after deposition. FIG. 33 is a stack diagram illustrating a N-type CQD layer 406 on the stack illustrated in FIG. 32 according to some aspects. An N-type CQD layer such as N-type layer 406 may be an intrinsically N-type HgTe layer. An N-type layer may be an intrinsically N-type HgTe layer that has been doped to produce a material that is more strongly N-type. An N-type layer may be an intrinsic HgTe layer that has been doped to produce a material that is N-type.

FIG. 34 is a stack diagram illustrating a top electrode 306 on the stack illustrated in FIG. 33 according to some aspects. The top electrode 306 may be a transparent conducting oxide (TCO) such as indium tin oxide (ITO), fluorine doped tin oxide (FTO), niobium doped anatase TiO2 (NTO), doped zinc oxide, etc. The top electrode 306 may be a transparent conducting film (TCF) such as a TCO, carbon nanotube network, graphene, organic polymers, etc. Techniques for fabricating graphene layers that are highly transparent to infrared light are known. Organic polymers that are highly transparent to infrared light may be derivatives of polyacetylene, polyaniline, polypyrrole or polythiophenes. The top electrode 306 can stay unpatterned when the substrate 110 and the bottom electrode 302 are a ROIC 202 and an input pad 201 of the ROIC 202. In some implementations, the top electrode may be patterned to enhance passage of photons to the active layer. The three semiconducting layers 403, 405, 406 form a NPN BJT 3400. The N-type layers 403, 406 are the collector and emitter of the BJT. The top electrode and the bottom electrode are the collector electrode and the emitter electrode of the BJT. The collector is contacting the collector electrode. The emitter electrode is contacting the emitter.

A variety of optoelectronic devices that can be light sensors used in conjunction with a ROIC. The light sensors include PINP phototransistors (FIGS. 10-14, 19), PIN photodiodes (FIGS. 15-18), PNP BJT phototransistors 3000 (FIG. 30), and NPN BJT phototransistors 3400 (FIG. 34). The light sensors include a number of semiconducting layers. The semiconducting layers include P-type quantum dot layers such as HgTe layers that are doped P-type. The semiconducting layers include N-type quantum dot layers such as intrinsic HgTe layers, and intrinsic HgTe layers that have been doped to be more strongly N-type. The semiconducting layers include polysilicon (poly-Si) layers. The semiconducting layers include N-type metal oxide semiconductor layers such as aluminum doped zinc oxide (AZO) layers, titanium oxide (TeO₂) layers, and zinc oxide (ZnO) layers.

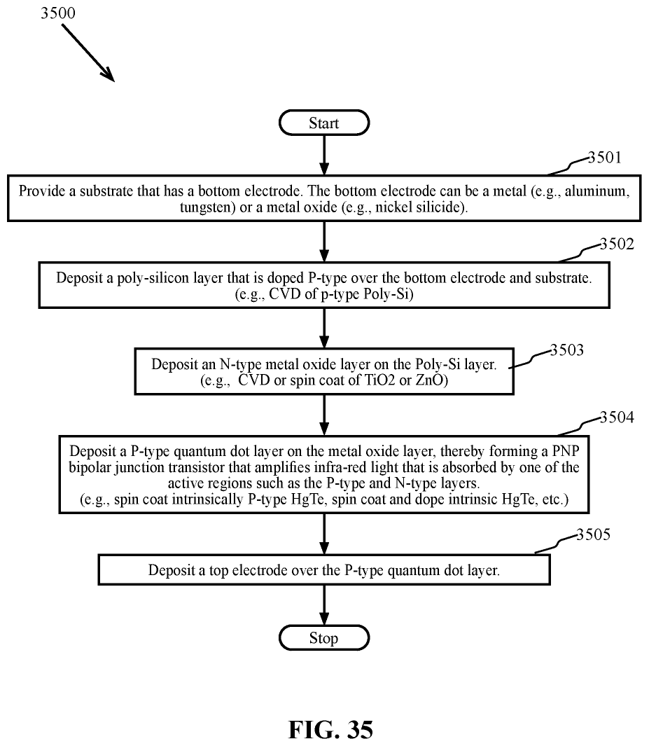

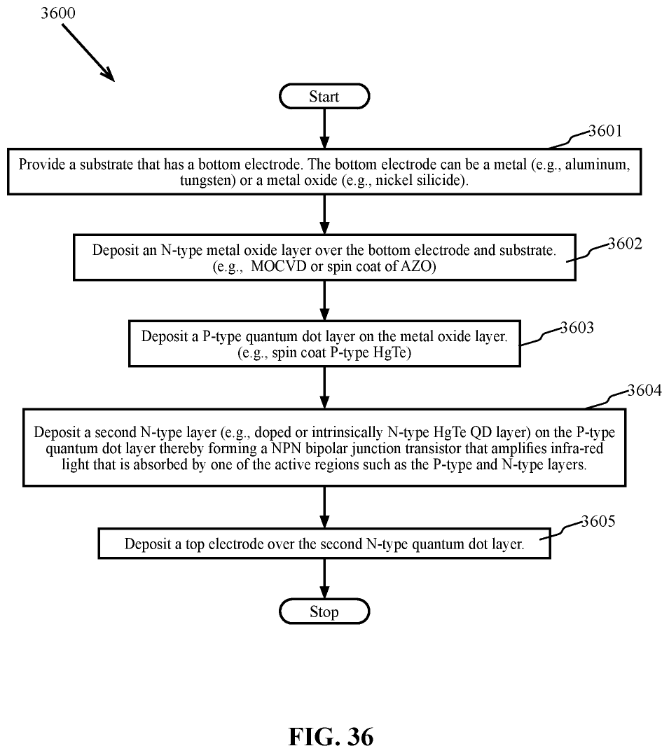

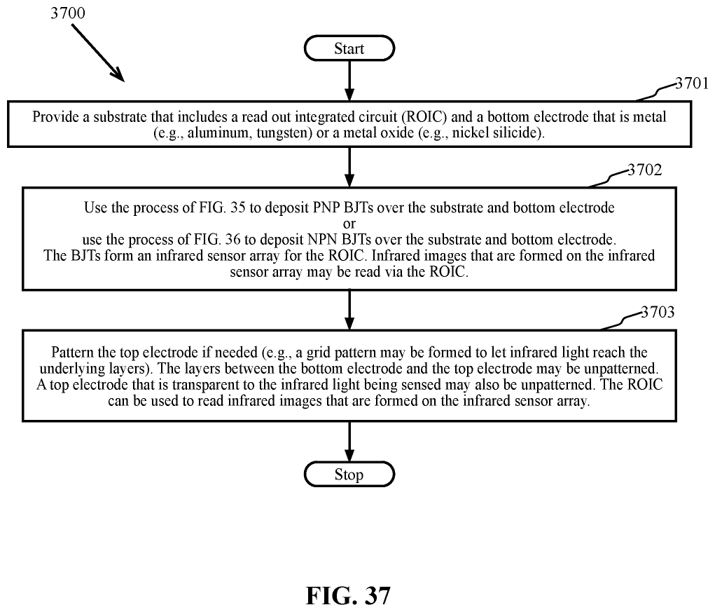

FIG. 35 is a high-level flow diagram illustrating a process for constructing an infrared light sensing PNP bipolar junction transistor (BJT) 3500 such as the PNP BJT of FIG. 30 according to some aspects. After the start, at step 3501 a substrate that has a bottom electrode can be provided. The bottom electrode can be a metal (e.g., aluminum, tungsten) or a metal oxide (e.g., nickel silicide). At step 3502, a poly-silicon layer that is doped P-type can be deposited over the bottom electrode and substrate (e.g., CVD of P-type Poly-Si). At step 3503 an N-type metal oxide layer can be deposited on the Poly-Si layer (e.g., MOCVD or spin coat of TiO2, ZnO, or AZO, etc.). At step 3504 a P-type quantum dot layer can be deposited on the metal oxide layer, thereby forming a PNP bipolar junction transistor that amplifies infra-red light that is absorbed by one of the active regions such as the P-type and N-type layers (e.g., spin coat N-type or intrinsic HgTe). At step 3505, a top electrode can be deposited over the P-type quantum dot layer.

FIG. 36 is a high-level flow diagram illustrating a process for constructing an infrared light sensing NPN BJT 3600 such as the NPN BJT of FIG. 34 according to some aspects. After the start, at step 3601 a substrate that has a bottom electrode can be provided. The bottom electrode can be a metal (e.g., aluminum, tungsten) or a metal oxide (e.g., nickel silicide). At step 3602, an N-type metal oxide layer can be deposited over the bottom electrode and substrate (e.g., MOCVD or spin coat of TiO2, ZnO, or AZO, etc. At step 3603, a P-type quantum dot layer can be deposited on the metal oxide layer (e.g., spin coat P-type HgTe, spin coat then dope the intrinsic HgTe, etc.). At step 3604, a second N-type layer (e.g., doped or intrinsic HgTe QD layer) can be deposited on the P-type quantum dot layer thereby forming a NPN bipolar junction transistor that amplifies infra-red light that is absorbed by one of the active regions such as the P-type and N-type layers. At step 3605, a top electrode can be deposited over the P-type quantum dot layer.

Nearly all of the steps of the process illustrated in FIG. 35 and FIG. 36 may be performed outside of a vacuum and all of the layers may stay unpatterned. As such, arrays of optoelectronic devices may be formed over ROICs via a series of simple and inexpensive processing steps such as spin coating. The optoelectronic devices are BJTs that produce photocurrents from input photons, amplify the photocurrents, and pass the amplified photocurrents to the input pads of an underlying ROIC.

FIG. 37 is a high-level flow diagram illustrating a process for constructing an infrared image sensor that uses BJTs as a sensor array 3700 according to some aspects. After the start, at step 3701 a substrate that includes a read out integrated circuit (ROIC) and a bottom electrode that is metal (e.g., aluminum, tungsten) or a metal oxide (e.g., nickel silicide) can be provided. The bottom electrode can be an input pad of the ROIC. At step 3602, BJTs are produced on the substrate. The BJTs can be produced via the process illustrated in FIG. 35 that deposits PNP BJTs over the substrate and bottom electrode. The BJTs can be produced via the process illustrated in FIG. 36 that deposits NPN BJTs over the substrate and bottom electrode. The BJTs form an infrared sensor array for the ROIC. Infrared images that are formed on the infrared sensor array may be read via the ROIC. At step 3603, the top electrode may be patterned if needed (e.g., a grid pattern may be formed to let infrared light reach the underlying layers). The layers between the bottom electrode and the top electrode may be unpatterned. A top electrode that is transparent to the infrared light being sensed may also be unpatterned. The ROIC can be used to read infrared images that are formed on the infrared sensor array.

Although the operations of the method(s) herein are shown and described in a particular order, the order of the operations of each method may be altered so that certain operations may be performed in an inverse order or so that certain operations may be performed, at least in part, concurrently with other operations. Instructions or sub-operations of distinct operations may be implemented in an intermittent and/or alternating manner.

Although specific aspects of the embodiments have been described and illustrated, the embodiments are not to be limited to the specific forms or arrangements of parts so described and illustrated. The scope of the invention is to be defined by the claims appended hereto and their equivalents.

What is claimed is:

1. An optoelectronic device comprising:
a substrate;
a bottom electrode at a top surface of the substrate;
a plurality of semiconducting layers deposited over the bottom electrode and the substrate; and
a top electrode deposited over the plurality of semiconducting layers,
wherein
the plurality of semiconducting layers forms a bipolar junction transistor (BJT) between the bottom electrode and the top electrode,
the top electrode and the bottom electrode are a collector electrode and an emitter electrode of the BJT,
the BJT includes a collector that is contacting the collector electrode,
the BJT includes an emitter that is contacting the emitter electrode, and the semiconducting layers include a BJT base formed at least in part using a quantum dot layer.

2. The optoelectronic device of claim 1, wherein light absorbed by one of the semiconducting layers produces a current that is amplified by the BJT.

3. The optoelectronic device of claim 1, wherein:
a first one of the semiconducting layers is deposited over the bottom electrode and the substrate;
a second one of the semiconducting layers is deposited over the first one of the semiconducting layers;
a third one of the semiconducting layers is deposited over the second one of the semiconducting layers;
the first one of the semiconducting layers is a P-type polysilicon layer;
the second one of the semiconducting layers is a N-type metal oxide layer; and
the third one of the semiconducting layers is a P-type quantum dot layer.

4. The optoelectronic device of claim 1, wherein:
a first one of the semiconducting layers is deposited over the bottom electrode and the substrate;
a second one of the semiconducting layers is deposited over the first one of the semiconducting layers;
a third one of the semiconducting layers is deposited over the second one of the semiconducting layers;
the first one of the semiconducting layers is a N-type metal oxide layer;
the second one of the semiconducting layers is a P-type quantum dot layer; and
the third one of the semiconducting layers is a N-type quantum dot layer that is doped N-type or intrinsically N-type.

5. The optoelectronic device of claim 4, wherein the second one of the semiconducting layers and the third one of the semiconducting layers are HgTe quantum dot layers.

6. The optoelectronic device of claim 1, wherein:
the semiconducting layers include a P-type quantum dot layer; and
the P-type quantum dot layer that is a HgTe quantum dot layer.

7. The optoelectronic device of claim 1, wherein the bottom electrode is a back side reflector configured to reflect at least 45% infrared light.

8. The optoelectronic device of claim 1, wherein the top electrode is configured to pass infrared light into the optoelectronic device.

9. The optoelectronic device of claim 1, wherein the top electrode is configured to pass at least 50% of normally incident infrared light into the optoelectronic device.

10. The optoelectronic device of claim 1, wherein:
a first one of the semiconducting layers is deposited over the bottom electrode and the substrate;
a second one of the semiconducting layers is deposited over the first one of the semiconducting layers;
a third one of the semiconducting layers is deposited over the second one of the semiconducting layers; and
the second one of the semiconducting layers is a photoactive region that absorbs photons and produces charge carriers.

11. The optoelectronic device of claim 1, wherein:
a first one of the semiconducting layers is deposited over the bottom electrode and the substrate;
a second one of the semiconducting layers is deposited over the first one of the semiconducting layers;
a third one of the semiconducting layers is deposited over the second one of the semiconducting layers; and
the second one of the semiconducting layers is configured to produce a plurality of charge carriers from a plurality of photons within an infrared wavelength range.

12. The optoelectronic device of claim 1, wherein:
a first one of the semiconducting layers is deposited over the bottom electrode and the substrate;
a second one of the semiconducting layers is deposited over the first one of the semiconducting layers;
a third one of the semiconducting layers is deposited over the second one of the semiconducting layers; and
the second one of the semiconducting layers is configured to produce a plurality of charge carriers from a plurality of photons within a wavelength range; and
the bottom electrode is configured to reflect the photons in the wavelength range.

13. The optoelectronic device of claim 12, wherein the top electrode is configured to pass the photons in the wavelength range into the optoelectronic device.

14. The optoelectronic device of claim 1, wherein:
the substrate includes a read-out integrated circuit (ROIC) and an array of bottom electrodes configured as a plurality of input pads of the ROIC;
the bottom electrodes include the bottom electrode;
the semiconducting layers and the top electrode form a plurality of BJTs; and
the BJTs form a focal plane array of an image sensor.

15. The optoelectronic device of claim 14, wherein light absorbed by one of the semiconducting layers produces a current that is amplified by the BJTs.

16. The optoelectronic device of claim 14, wherein the semiconducting layers stay unpatterned.

17. The optoelectronic device of claim 14, wherein the semiconducting layers and the top electrode stay unpatterned.

18. An optoelectronic device comprising:
a substrate that includes a read-out integrated circuit (ROIC) that includes an array of input pads;
a plurality of semiconducting layers deposited over the input pads and the substrate; and
a top electrode deposited over the plurality of semiconducting layers, wherein
the plurality of semiconducting layers forms a plurality of BJTs between the input pads and the top electrode,
the BJTs include a plurality of collectors and a plurality of emitters,
the top electrode and the input pads are collector electrodes and emitter electrodes of the BJTs,
the collectors are contacting the collector electrodes,
the emitters are contacting the emitter electrodes,
the semiconducting layers include a P-type quantum dot layer,
the semiconducting layers include a N-type metal oxide layer, and
the BJTs form a focal plane array of an image sensor.

19. The optoelectronic device of claim 18, wherein the semiconducting layers and the top electrode are unpatterned layers.

20. A method comprising:
obtaining a substrate that has a bottom electrode at a top surface of the substrate;
depositing a plurality of semiconducting layers over the bottom electrode and the substrate; and
depositing a top electrode over the plurality of semiconducting layers,
wherein
the plurality of semiconducting layers forms a bipolar junction transistor (BJT) between the bottom electrode and the top electrode,
the top electrode and the bottom electrode are a collector electrode and an emitter electrode of the BJT,
the BJT includes a collector contacting the collector electrode,
the BJT includes an emitter contacting the emitter electrode,
the plurality of semiconducting layers includes a P-type quantum dot layer, and
the plurality of semiconducting layers includes a N-type metal oxide layer.
